(19) United States
(12) Patent Application Publication
(10) Pub. No.: US 2003/0080418 A1
(43) Pub. Date: May 1, 2003

(54) SEMICONDUCTOR DEVICE HAVING POWER SUPPLY PADS ARRANGED BETWEEN SIGNAL PADS AND SUBSTRATE EDGE

(76) Inventors: MOTOO SUWA, OME (JP); TAKASHI MIWA, FUSSA (JP)

Correspondence Address: MATTINGLY, STANGER & MALUR, P.C., 1800 DIAGONAL ROAD, SUITE 370, ALEXANDRIA, VA, 22314, US

(21) Appl. No.: 09/424,929

(22) PCT Filed: Sep. 7, 1998
(86) PCT No.: PCT/JP98/04004

(30) Foreign Application Priority Data
Sep. 9, 1997 (JP) 9-243867

(51) Int. Cl. H01L 23/48

(52) U.S. Cl. 257/737

(57) ABSTRACT

General-purpose properties are imparted to a base substrate mounting a semiconductor chip thereon so that one type of base substrate is responsible for a design change of a semiconductor chip or mounting of different types of semiconductor chips.

A semiconductor chip-mounting region is provided on one surface of an insulating sheet-shaped substrate, external terminals for signal and external terminals for power supply are provided on the other surface. With respect to the external terminals for signal or power supply, which are, respectively, connected at one end thereof with external electrodes of the semiconductor chip mounted on the one surface and at the other end with the external terminals on the other surface, end portions of the signal wirings are provided around the semiconductor chip-mounting region on the one surface and end portions of the power supply wirings are provided outwardly of the end portions of the signal wirings.

The wirings for power supply are provided outward of the signal wirings, so that even if external electrodes for power supply of a semiconductor chip are arranged at any positions, they can be readily connected with power supply wirings by means of a bonding wire.

### TECHNICAL FIELD

This invention relates to a semiconductor device mounting semiconductor chips on a base substrate and more particularly, to a technique which is effective when applied to a semiconductor device provided with an array of external terminals on a back side of a base substrate.

### TECHNICAL BACKGROUND

Semiconductor integrated circuit devices, such as LSI and the like, have more complicated circuits mounted therein with their function becoming higher as the degree of integration is more improved. Such high functionality leads to a corresponding increase in number of external electrodes (bonding pads) provided at a semiconductor chip mounted on the LSI and also of the external terminals of a semiconductor device (package) mounting the semiconductor chip.

In order to cope with such an increase in number of external terminals of a semiconductor device, there have been developed semiconductor devices including BGA (ball grid array) wherein projected electrodes serving as external terminals are provided in the form of lattices at a bottom surface, and LGA (lead grid array) wherein flat electrodes serving as external terminals are provided in the form of lattices at a bottom surface.

Such a semiconductor device is so arranged that a semiconductor chip is mounted on one surface (taken as a front surface side) on an insulating base substrate made of a resin, a ceramic material or the like, and external terminals of the semiconductor device are provided on the other surface (taken as a back surface side) of the base substrate in the form of lattices, under which the external electrodes of the semiconductor chip and the external terminals of the base substrate are connected via wirings provided in the base substrate.

In this type of prior art semiconductor device, the external terminals are provided outwardly of a semiconductor chip-mounting region of the base substrate. In general, the external electrodes of the semiconductor chip and wirings provided on the base substrate are connected via wire bonding in the vicinity of the semiconductor chip. The wirings are further lead outwardly of the base substrate for connection with external terminals provided at the peripheral portion on the other surface of the base electrode via a through-hole formed in the base substrate.

In recent years however, in order to meet the requirement for miniaturization of semiconductor devices, it is necessary to further miniaturize a base substrate for semiconductor devices such as FBGA (Fine pitch Ball Grid Array). To this end, external terminals are provided not only on the peripheral portion of the base substrate, but also on the central portion of the base substrate, i.e. a portion corresponding to the back surface side of a semiconductor chip-mounting region. Accordingly, the connection between the semiconductor chip and the external terminal is achieved such that a wiring located on one surface of the base substrate and in the vicinity of the semiconductor chip is connected at one end thereof with an external electrode of the semiconductor chip via wire bonding, and the wiring is taken inwardly of the base substrate (i.e. the back surface side of the semiconductor chip) and connected to a wiring on the other surface via a through-hole so that the other end of the wiring is connected with an external terminal.

With the base substrate of the above-stated semiconductor device, there is provided a wiring for a signal such as a control signal, an address signal, a data signal or the like and a wiring for an electric supply such as for a power supply potential, a ground potential or the like. In order to ensure the stability of a power supply potential and the reduction of a heat resistance, there is used a board having a multilayered printed wiring structure and it has been in frequent use to provide a sheet-shaped wiring layer for power supply as an inner layer.

However, with such a structure, limitation is placed on the application of the wiring connected to the sheet-shaped wiring layer only to the wiring for power supply, so that an external electrode for power supply of a semiconductor chip to be mounted should be located at a position corresponding to the wiring. Accordingly, in case where the positions of external electrodes of semiconductor chips differ from each other for the semiconductor chips which have substantially the same arrangement, separate base substrates corresponding to the positions have had to be furnished.

This, in turn, requires a base substrate for every type of semiconductor chip, and thus, the manufacture and control of base substrates has become complicated. It has been experienced that if positions of external electrodes are changed depending on the change of design for the same type of semiconductor chip, the base substrate has to be changed, thus influencing the manufacture of semiconductor devices. Such a base substrate is set out, for example, in “Nikkei Electronics” published by Nikkei BP Co., Ltd. (1994, no. 601, pp. 60 to 67).

The object of the invention is to provide a technique which is able to impart general-purpose properties to a base substrate and which enables one base substrate to be responsible for a design change of a semiconductor chip or mounting of different types of semiconductor chips.

The above and other objects and novel features of the invention will become apparent from the description of the present specification and the accompanying drawings.

### DISCLOSURE OF THE INVENTION

Among the inventions disclosed in this application, typical ones are simply described below with respect to the outlines thereof.

In a semiconductor device of the type wherein a semiconductor chip is mounted on one surface of a base substrate and external terminals for signal and external terminals for power supply are, respectively, provided on the other surface thereof, and wirings or interconnections for signal provided on the base substrate or wirings for power supply are connected, at one end thereof, with the external electrodes of the semiconductor chip on the one surface and, at the other end, with the external terminals on the other surface, the end portions of the wirings for signal are provided around the semiconductor chip on the one surface and the end portions of the wirings for power supply are provided circularly at the outside of the end portions of the wirings for signal.

In a semiconductor device of the type wherein a semiconductor chip is mounted on one surface of a base substrate and external terminals are provided on the other surface, and wirings formed on the base substrate are connected, at one end thereof, to external electrodes of the semiconductor chip on the one surface and are connected, at the other end thereof, to external terminals on the other surface, the external terminals provided above include external terminals for signal and external terminals for power supply wherein the end portions of the wirings for signal connected with the external terminals for signal are provided around the semiconductor chip on the one surface and the end portions of the wirings for power supply connected with the external terminals for power supplies are formed outwardly of the end portions of the wirings for signal in the form of a rectangular circle or a divided rectangular circle.

Further, in a semiconductor device of the type wherein a semiconductor chip is mounted on one surface of a base substrate and external terminals are provided on the other surface, and wirings formed on the base substrate are connected, at one end thereof, to external electrodes of the semiconductor chip on the one surface and are connected, at the other end thereof, to external terminals on the other surface, the external terminals include external terminals for signal and external terminals for power supply wherein the end portions of the wirings for signal connected with the external terminals for signal are provided around the semiconductor chip on the one surface and the end portions of the wirings for power supply connected with the external terminals for power supply are formed outwardly of the end portions of the rectangular circle-shaped wirings for signal divided at corners.

According to the measures set out above, the wirings for power supply are outwardly of the wirings for signal in the form of a circle, so that even if external electrodes for power supply of a semiconductor chip are arranged at any position, they can be readily connected with the wirings for power supply by means of a bonding wire. This enables one to mount, on the same base substrate, each of semiconductor chips having external electrodes for power supply whose arrangements differ from one another.

### BRIEF DESCRIPTION OF THE DRAWINGS

FIG. 1 is a plan view showing a base substrate of a semiconductor device according to one embodiment of the invention.

FIG. 2 is a longitudinal section of the base substrate shown in FIG. 1.

FIG. 3 is a plan view showing the semiconductor device according to the one embodiment of the invention.

FIG. 4 is a longitudinal section of the semiconductor device shown in FIG. 3.

FIG. 5 is a plan view showing a base substrate of a prior-art semiconductor device.

FIG. 6 is a plan view showing the prior-art semiconductor device.

FIG. 7 is a longitudinal section of the semiconductor device shown in FIG. 6.

FIG. 8 is a plan view showing a semiconductor device according to another embodiment of the invention.

FIG. 9 is a longitudinal section of the semiconductor device shown in FIG. 8.

FIG. 10 is a plan view showing a base substrate of a semiconductor device according to a further embodiment of the invention.

FIG. 11 is a plan view showing a semiconductor device according to a still further embodiment of the invention.

FIG. 12 is a longitudinal section of the semiconductor device shown in FIG. 11.

### BEST MODE FOR CARRYING OUT THE INVENTION

Embodiments of the invention are described below.

It should be noted that throughout the drawings illustrating the embodiments, like reference numerals indicate those having a similar function, which are not repeatedly explained.

(Embodiment 1)

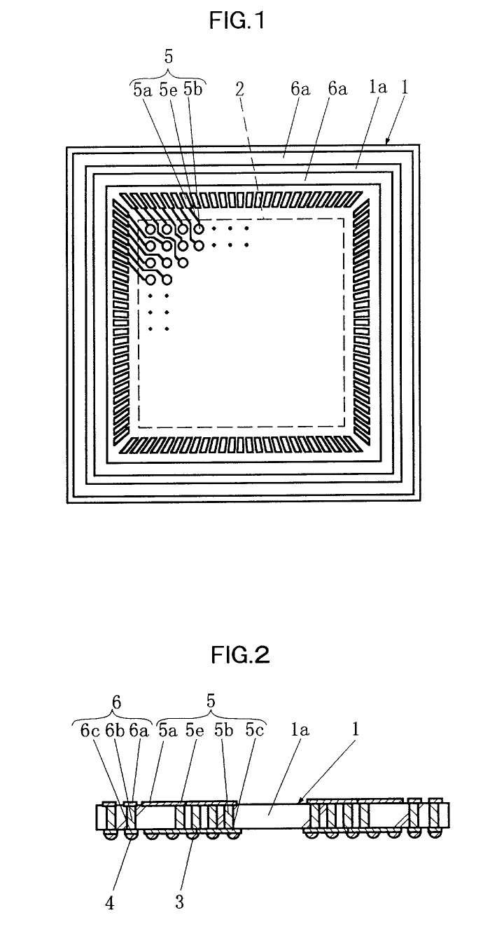

FIG. 1 is a plan view of a base substrate of a semiconductor device according to one embodiment of the invention, and FIG. 2 is a longitudinal section of the base substrate shown in FIG. 1.

In the figures, reference numeral 1 indicates a base substrate including a substrate 1 obtained by shaping an insulating resin, such as bismaleidotriazine, in the form of a sheet and wirings 5, 6 formed thereon. A semiconductor chip is mounted on a semiconductor chip-mounting region 2 indicated at the center of the substrate 1a by broken lines. External terminals 3, 4 of a semiconductor device are formed on the other surface, which is in face-to-face relation with one surface shown in the figure, in the form of lattices.

The substrate 1a is provided with the wirings 5, 6 which are, respectively, connected at one end thereof with external terminals 3, 4 and at the other end with external electrodes of the semiconductor chip. The external terminals 3, 4 include the external terminal 3 for a signal such as a control signal, an address signal, a data signal or the like and the external terminal 4 for a power supply such as a power supply potential, a ground potential or the like. As the wirings 5, 6 connected with these external terminals 3, 4, there are provided the wiring 5 for a signal such as a control signal, an address signal, a data signal or the like, and the wiring for a power supply such as a power supply potential, a ground potential or the like.

The wiring for the signal is comprised of a wide pad wiring layer 5a, which serves as a connection point for wire bonding and is formed on the one surface on which the semiconductor chip is mounted and connected with the external electrode of the mounted semiconductor chip, a connection wiring layer 5e connected with the pad wiring layer 5a, an in-through-hole wiring layer 5b connected with the connection wiring layer 5e, and a wiring layer 5c connected with the in-through-hole wiring layer 5b and formed on the other surface on which the external terminals 3, 4 are formed. The wiring layer 5c is connected with the external terminal 3.

The wiring 6 for power supply is comprised of a rectangular circle-shaped pad wiring layer 6a which serves as a connection point for wire bonding for which is formed on the one surface on which the semiconductor chip is mounted and connected with the external electrode of the mounted semiconductor chip, an in-through-hole wiring layer 6b connected with the wiring layer 6a, and an wiring layer 6c which is connected with the in-through-hole wiring layer 6b and formed on the other surface on which the external terminal 4 is provided wherein the wiring layer 6c is connected with the external terminal 4.

In this embodiment, the pad wiring layers 5a for signal are provided in the proximity to the surrounding of the semiconductor chip-mounting region 2, and the pad wiring layers 6a for power supply are provided outwardly of the pad wiring layers 5a for signal in the form of a rectangular circle. It will be noted that the pad wiring layer 6a for power supply includes a wiring layer for power supply potential and a wiring layer for ground potential which are provided in the form of a double ring.

It will be noted that the pad wiring layers 6a are formed as having a minimum line width and a minimum interval necessary for bonding, enabling the influence on the dimension of the base substrate 1 to be suppressed only slightly.

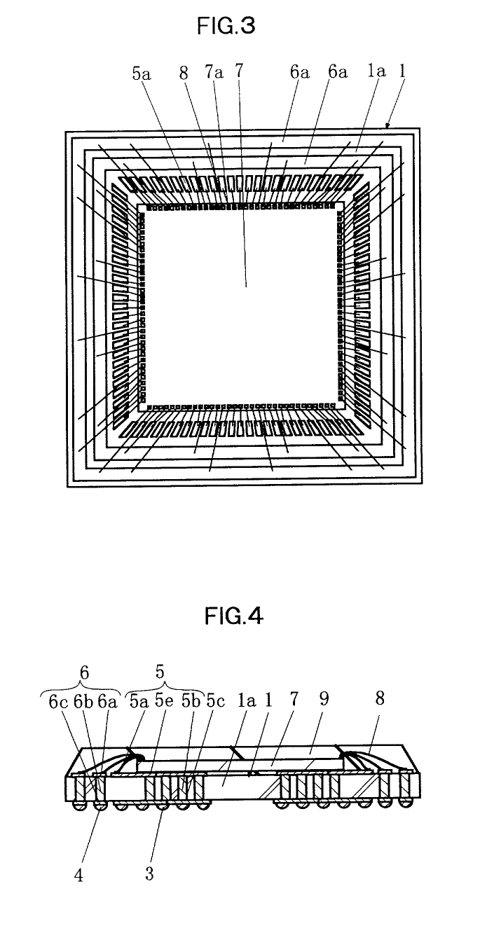

FIG. 3 is a plan view showing a semiconductor device wherein a semiconductor chip is mounted on the base substrate 1 and subjected to wire bonding, and FIG. 4 is a longitudinal section of the semiconductor device shown in FIG. 3.

A semiconductor chip 7 is mounted on the sheet-shaped substrate 1a of the base substrate 1 substantially at the center thereof, and an external electrode 7a of the semiconductor chip 7 and the pad wiring layers 5a, 6a are, respectively, connected via a bonding wire 8. It will be noted that the entire surface of the base substrate 1 except the pad wiring layers 5a, 6a is covered with a solder resist (insulating film, not shown), and the semiconductor chip 7 and the wiring 5 are insulated and separated from each other by means of the solder resist (insulating film)

After the mounting of the semiconductor chip 7 and the completion of wire bonding, a sealing body 9 such as by potting with a resin is formed on the one surface of the base substrate 1, thereby sealing the semiconductor chip 7, the bonding wire 8 and the wiring layers 5a, 5e and 6a.

Since the pad wiring layer 6a for power supply is provided outwardly of the pad wiring layer 5a for signal, the external electrode 7a for power supply of the semiconductor chip 7 may be readily connected to the pad wiring layer 6a for power supply and the bonding wire 8 even if the electrode 7a is arranged at any position. To this end, any types of semiconductor chips, which have different arrangements of external electrodes for power supply, can be mounted on the same type of base substrate.

For instance, with a semiconductor chip mounting logic elements wherein there appears a remarkable tendency toward high pin counts, the number of external electrodes for power supply amounts to about 30 or 40% of the total number of electrodes. Accordingly, when semiconductor chips having different arrangements of external electrodes can be mounted on the same type of base substrate, the general-purpose properties of the base substrate can be extended.

Moreover, since the pad wiring layer 6a for power supply is provided outwardly of the pad wiring layer 5a for signal, the inwardly provided pad wiring layer 5a for signal is unlikely to have an influence from outside owing to the shielding effect of the pad wiring layer 6a.

In addition, since the pad wiring layer 6a for power supply is provided outwardly, the layout of the connection wiring layer 5e for signal is not impeded, thus being adapted to high pin counts and miniaturization.

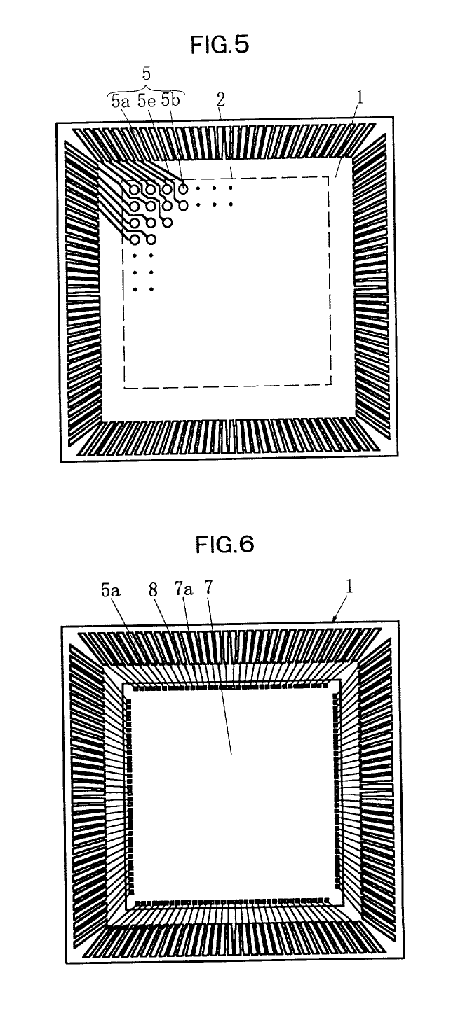

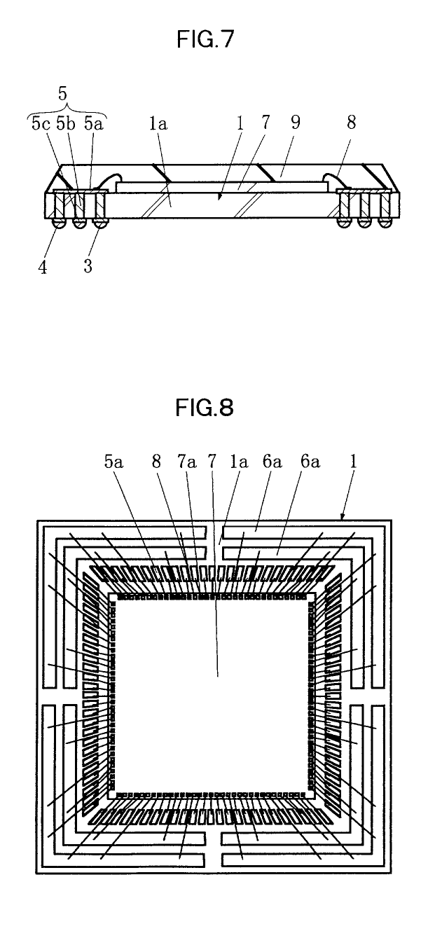

FIGS. 5 to 7, respectively, show a prior-art base substrate and a semiconductor device using the base substrate.

Like the foregoing embodiment, a semiconductor chip 7 is mounted at the center of a substrate 1a formed of an insulating resin in the form of a sheet, and external terminals 3,4 of a semiconductor device are formed on an opposite surface, which is in face-to-face relation with the one surface shown in the figures, in the form of lattices.

Wirings 5, 6, which are, respectively, connected to the external terminals 3, 4 at one end thereof and also to external electrodes of the semiconductor chip on the one surface at the other end thereof, are formed on the substrate 1a (wherein the wiring 6 is not particularly shown because it is like the wiring 5). As the external terminals 3, 4, there are provided the external terminal 3 for a signal such as a control signal, an address signal, a data signal or the like, and the external terminal 4 for a power supply such as a power supply potential, a ground potential or the like. As wirings 5, 6 connecting with these external terminals 3, 4, there are provided the wiring 5 for a signal such as a control signal, an address signal, a data signal or the like and a wiring 6 for a power supply such as a power supply potential, a ground potential or the like.

The wirings 5, 6, respectively, include wide pad wiring layers 5a, 6a serving as connection points of wire bonding which are formed on one surface on which the semiconductor chip is mounted and connected with external electrodes of the semiconductor chip, connection wiring layers 5e, 6e connected to the pad wiring layer 5a, in-through-hole wiring layers 5b, 6b, respectively, connected with the connection wiring layers 5e, 6e, and wiring layers 5c, 6c, respectively, connected with the in-through-hole wiring layers 5b, 6b and formed on the other surface on which the external terminals 3, 4 are formed. The wiring layers 5c, 6c are, respectively, connected to the external terminals 3, 4.

The external terminals 3, 4 are provided outwardly of a semiconductor chip-mounting region 2 of the base substrate 1. The pad wiring layers 5a, 6a are subjected to bonding with external electrodes 7a of the semiconductor chip 7 at one end thereof in the vicinity of the semiconductor chip 7. Thus, the pad wiring layers 5a, 6a are led outwardly of the substrate 1a of the base substrate 1 and connected with the in-through-hole wiring layers 5b, 6b, and are eventually connected to the external terminals 3, 4 via the wiring layers 5c, 6c on the other surface, which, in turn, are connected with the in-through-hole wiring layers 5b, 6b. The pad wiring layers 5a, 6a for signal and power supply are all provided in the proximity to the periphery of the semiconductor chip 7.

Accordingly, where the external electrodes 7a for power supply of the semiconductor chip 7 are changed in position depending on the design change, it becomes difficult to connect between the pad wiring layer 6a for power supply and a corresponding external electrode 7a. Thus, another type of base substrate becomes necessary for the change.

With the prior art counterpart, where the pad wiring layers 5a, 6a are large in number, such a case may occur where the dimension of the base substrate has to be increased in view of the limitation on layout. In this embodiment, the pad wiring layers 5a for signal alone are provided adjacently to the periphery of the semiconductor chip 7, so that the wiring layers provided around the periphery is reduced in number, not involving such a problem as mentioned above.

(Embodiment 2)

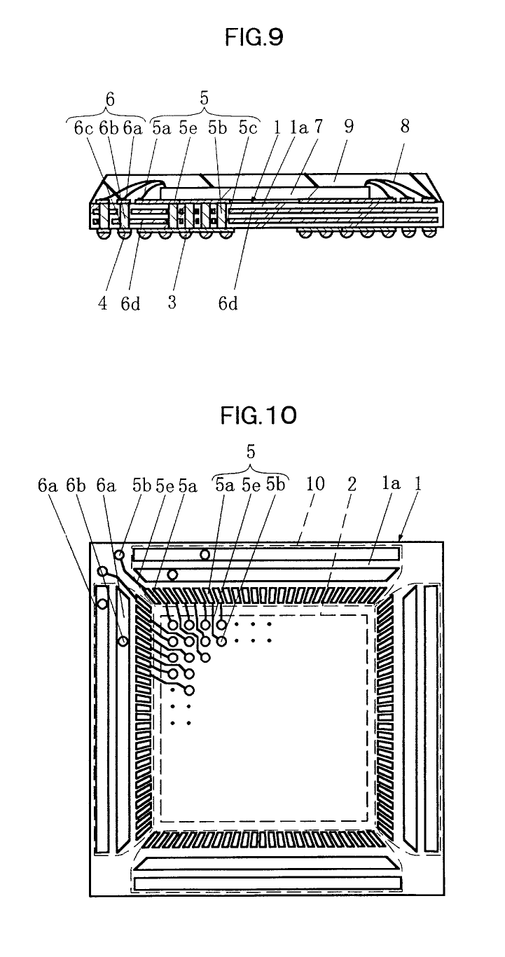

FIG. 8 is a plan view of a semiconductor device according to another embodiment of the invention, and FIG. 9 is a longitudinal section of the semiconductor device shown in FIG. 8.

A base substrate 1 has wirings 5, 6 formed on a substrate 1a shaped of an insulating resin, such as bismaleidotriazine or the like, in the form of a sheet, a semiconductor chip 7 mounted at the center thereof, and external terminals 3, 4 of a semiconductor device provided in the form of lattices on other surface which is facing with one surface shown in the figure.

The wirings 5, 6 formed on the substrate 1a are, respectively, connected at one end thereof with the external terminals 3, 4 and at the other end with external electrodes 7a of the semiconductor chip 7. The external terminals 3, 4 include the external terminal for a signal such as a control signal, an address signal, a data signal or the like, and the external terminal 4 for a power supply such as a power supply potential, a ground potential or the like. The wirings 5, 6 connected with these external terminals 3, 4 include the wiring 5 for a signal such as a control signal, an address signal, a data signal or the like and the wiring 6 for a power supply such as a power supply potential, a ground potential or the like.

The wiring 5 for the signal comprises a wide pad wiring layer 5a serving as a connection point for wire bonding which is formed on the one surface on which the semiconductor chip is mounted and is connected with the external electrode of the mounted semiconductor chip, a connection wiring layer 5e connected with the pad wiring layer 5a, an in-through-hole wiring layer 5b connected with the connection wiring layer 5e, and a wiring layer 5c connected with the in-through-hole wiring layer 5b and formed on the other surface on which the external terminals 3, 4 are provided. The wiring layer 5c is connected with the external terminal 3.

The wiring 6 for the power supply includes a rectangular circle-shaped pad wiring layer 6a which serves as a connection point for wire bonding and is formed on the one surface, on which the semiconductor chip is mounted and connected with the external electrode of the mounted semiconductor chip, an in-through-hole wiring layer 6b connected with the wiring layer 6a, and a wiring layer 6c connected with the in-through-hole wiring layer 6b and formed on the other surface on which the external terminal 4 is formed, wherein the wiring layer 6c is connected with the external terminal 4.

It will be noted that the base substrate 1 is covered with a solder resist (insulating film, not shown) over the entire surface except the regions of the pad wiring layers 5a, 6a, and the semiconductor chip and the wiring 5 are insulated and separated by means of the solder resist (insulating film).

After mounting of the semiconductor chip 7 and completion of wire bonding, a sealing body 9 is formed on the other surface of the base substrate 1 such as by potting of a resin, thereby sealing the semiconductor chip 7, the bonding wire 8 and the wiring layers 5a, 5e, 6a.

In this embodiment, the pad wiring layers 5a for signal are provided adjacently to the periphery of the semiconductor chip-mounting region 2, and the pad wiring layers 6a for power supply are formed outwardly of the pad wiring layers 5a for signal in the form of a rectangular circle. As the pad wiring layer 6a for power supply, there are provided a wiring layer for power supply potential and a wiring layer for ground potential which are in the form of a double ring, and the pad wiring layers 6a of the respective layers are formed in the form of a circle which is divided at a center of each side. It is to be noted that the pad wiring layer 6a is able to suppress an influence on the dimension of the base substrate 1 only slightly when formed at a minimum line width and a minimum space necessary for bonding.

Since the pad wiring layers 6a for power supply are formed outwardly of the pad wiring layers 5a for signal in the form of a divided rectangular circle, the external electrode 7a for power supply of the semiconductor chip 7 can be readily connected with the pad wiring layer 6a for power supply by means of the bonding wire irrespective of the position where the external electrode is arranged. The enables one to mount different types of semiconductor chips having external electrodes for power supply whose positions differ from each other on the same type of base substrate.

For instance, with a logic-mounting semiconductor chip in which there appears a remarkable tendency toward high pin counts, the number of external electrodes for power supply amounts to 30 or 40% of the total electrodes. If semiconductor chips of the types which have different positions of external electrodes can be mounted on the same type of base substrate, the general-purpose properties of the base substrate can be enlarged.

Moreover, the pad wiring layer 6a is divided in this embodiment. Using this arrangement, where wirings other than wirings for power supply have to be arranged because of the arrangement of external terminals, other wirings may be arranged at the divided portions. In addition, taking into account adhesion with a resin which is a material for the sealing body 9, adhesion with a base substrate material such as a resin is better than adhesion with a pad wiring layer plated with gold or the like, thereby ensuring improved sealing properties of the sealing body.

Since the pad wiring layers 6a for power supply are formed outwardly of the pad wiring layers 5a for signal, the inside pad wiring layer 5a for signal is unlikely to suffer an influence from outside by the shielding effect of the pad wiring layer 6a.

Moreover, the pad wiring layer 6a for power supply is provided at the outside, so that the layout of the connection wiring layer 5e for signal is not impeded.

In this embodiment, the base substrate 1 used is a four-layered substrate having two inner layers wherein the inner layers are, respectively, connected with the wirings 6 for power supply potential and signal in the form of a sheet-shaped wiring layer 6d. In the embodiment shown in the figures, this wiring layer 6d is connected to the in-through-hole wiring layer 6b. In this connection, however, the pad wiring layer 6a and the wiring layer 6d may be connected through a via hole wiring layer which longitudinally passes through the respective layers wherein the wiring 6 is properly arranged by use of the wiring layer 6d, and the wiring layer 6d and the wiring layer 6c are connected to each other through another via hole wiring layer.

The provision of the wiring layer 6d enables an inductance to be reduced and the degree of freedom for the formation of wirings to be increased.

(Embodiment 3)

FIG. 10 is a plan view showing a base substrate of a semiconductor device according a further embodiment of the invention.

In the figure, reference numeral 1 indicates a base substrate which includes wirings 5, 6 formed on a substrate 1a shaped of an insulating resin, such as bismaleidotriazine or the like, in the form of a sheet. A semiconductor chip is mounted on a semiconductor chip-mounting region 2 shown at the center of the substrate 1a surrounded by broken lines. External terminals 3, 4 of the semiconductor device are formed, as lattices, on the other surface opposite to one surface shown in the figure.

The substrate 1a is provided with wirings 5, 6 which are connected at one end thereof with the external terminals 3, 4 and at the other end with the external electrodes of the semiconductor chip on the one surface. As the external terminals 3, 4, there are provided the external terminal 3 for a signal such as a control signal, an address signal, a data signal or the like and the external terminal 4 for a power supply such as a power supply potential, a ground potential or the like. As the wirings 5, 6 connected with these external terminals 3, 4, there are provided the wiring 5 for a signal such as a control signal, an address signal, a data signal or the like and the wiring 6 for a power supply such as a power supply potential, a ground potential or the like.

The wiring 5 for the signal consists of a wide pad wiring layer 5a serving as a connection point for wire bonding which is formed on the one surface on which the semiconductor chip is mounted and is connected with the external electrode of the mounted semiconductor chip, a connection wiring layer 5e connected with the pad wiring layer 5a, an in-through-hole wiring layer 5b connected with the connection wiring layer 5e, and a wiring layer 5c connected with the in-through-hole wiring layer 5b and formed on the other surface on which the external terminals 3, 4 are provided, wherein the wiring layer 5c is connected with the external terminal 3.

The wiring 6 for the power supply includes a rectangular circle-shaped pad wiring layer 6a which serves as a connection point for wire bonding and is formed on the one surface, on which the semiconductor chip is mounted and connected with the external electrode of the mounted semiconductor chip, an in-through-hole wiring layer 6b connected with the wiring layer 6a, and a wiring layer 6c connected with the in-through-hole wiring layer 6b and formed on the other surface on which the external terminal 4 is formed, wherein the wiring layer 6c is connected with the external terminal 4.

It will be noted that the base substrate 1 is covered with a solder resist 10 (insulating film) over the entire surface at the front side except the regions of the pad wiring layers 5a, 6a (indicated by broken lines in FIG. 10) and also over the entire surface at the back side except the external terminals 3, 4, and the wirings 5, 6 except a connection region thereof are insulated and covered with the solder resist (insulating film) 10.

In this embodiment, the pad wiring layers 5a for signal are provided adjacently to the periphery of the semiconductor chip-mounting region 2, and a wiring layer for power supply potential and a wiring layer for signal are provided, as the pad wiring layer 6a for power supply, in the form of a double ring outwardly of the pad wiring layers 5a for the signal. Individual pad wiring layers 6a are formed as a circle divided at ends of the respective sides thereof. This division permits the connection wiring layer 5e of the wiring 5 for signal and the in-through-hole wiring layer 5b to be arranged at corners of the substrate 1a where no pad wiring layer 6a for power supply is formed.

It will be noted that the pad wiring layers 6a are formed as having a minimum line width and a minimum space necessary for bonding, thus enabling one to suppress an influence on the dimension of the base substrate 1 only in a slight degree.

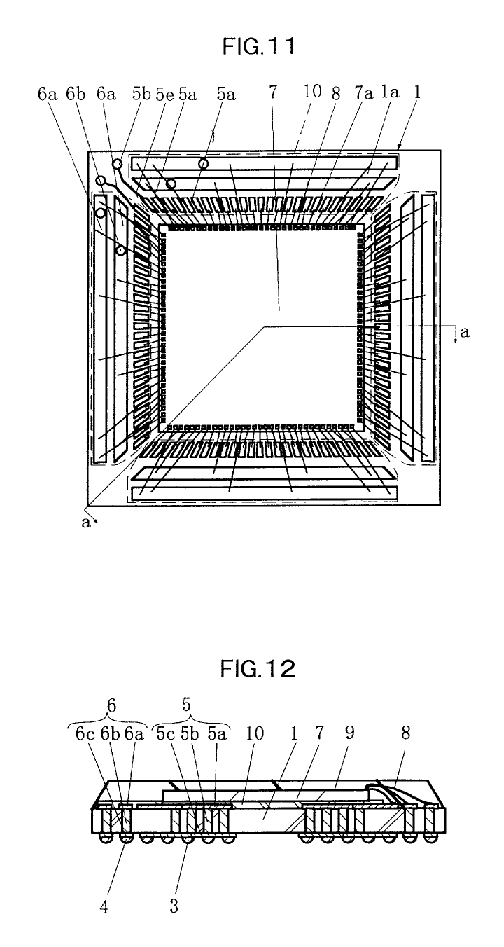

FIG. 11 is a plan view of a semiconductor device wherein a semiconductor chip is mounted on the base substrate 1 shown in FIG. 10 and subjected to wire bonding, and FIG. 12 is a longitudinal section taken along the a-a line of the semiconductor device shown in FIG. 11.

The semiconductor chip 7 is mounted substantially at the center of the sheet-shaped substrate 1a of the base substrate 1, and the external electrodes 7a of the semiconductor chip are, respectively, connected with the pad wiring layers 5a, 6a through bonding wires.

After completion of the mounting of the semiconductor chip 7 and the completion of the wire bonding, a sealing body 9 is formed on the one surface of the base substrate 1 such as by potting of a resin, so that the semiconductor chip 7, bonding wires 8 and wiring layers 5a, 5e and 6a are sealed.

In this embodiment, the pad wiring layers 5a are provided adjacently to the periphery of the semiconductor-mounting region 2, and the pad wiring layers 6a for power supply are provided outwardly of the pad wiring layers 5a for the signal as having a double ring structure including a wiring layer for power supply potential and a wiring layer for ground potential. The respective pad wiring layers 6a are formed as a circle divided at ends of each side. This division permits the connection wiring layer 5e and the in-through-hole wiring layer 5b of the wiring 5 for signal to be arranged at the corners of the substrate 1a where no pad wiring layer 6a for power supply is provided. The entire surface at the front side except the regions of the pad wiring layers 5a, 6a (indicated by broken lines in FIG. 10) and the entire surface at the back side except the regions of the external terminals 3, 4 are, respectively, covered with a solder resist (insulating film) 10, and the wirings 5, 6 are insulated and covered with a solder resist (insulating film) 10.

The pad wiring layers 6a for power supply are provided outwardly of the pad wiring layers 5a for signal in the form of a divided rectangular circle, so that even if the external electrode 7a for power supply of the semiconductor chip 7 is arranged at any position, it can be readily connected by means of the pad wiring layer 6a for power supply and the bonding wire 8. This enables one to mount semiconductor chips having different arrangements of external electrodes for power supply on the same type of base substrate, respectively.

For instance, with a semiconductor chip mounting logic elements wherein there is a remarkable tendency toward high pin counts, the number of external terminals for power supply amounts to 30 to 40% of the total electrodes. Such semiconductor chips which have different arrangements of external electrodes may be mounted on the same type of base substrate, respectively. Thus, the general-purpose properties of the base substrate are enlarged.

In this embodiment, the connection wiring layer 5e and the in-through-hole wiring layer 5b of the wiring 5 for signal are arranged at the respective corners of the substrate 1a where no pad wiring layer 6a for power supply is not provided. This arrangement makes it possible to arrange wirings other than the wirings for power supply at the corner portions if such wirings other than those for power supply is necessary in view of a layout or the like, and is thus suitable for high pin counts and miniaturization.

Taking adhesion to a resin for a sealing body 9 into account, the sealing properties of the sealing body 9 can be improved. This is because the adhesion between the base substrate 1a made of a resin or the like or the solder resist (insulating film) 10 and a sealing resin for the sealing body 9 is higher than adhesion to the pad wiring layer 6a plated with gold or the like. Since the solder resist (insulating film) 10 and the sealing resin for the sealing body 9 are bonded at the corner portions undergoing an increasing thermal stress, the improving effect is great.

Moreover, the pad wiring layer 6a for power supply is provided outwardly of the pad wiring layer 5a for signal, so that the inner pad wiring layer 5a is unlikely to suffer an influence from outside owing to the shielding effect of the pad wiring layer 6a.

In addition, since the pad wiring layer 6a for power supply is provided outwardly, the layout of the connection wiring layer 5e for signal is not impeded, and is thus suitable for high pin counts and miniaturization.

In this embodiment, a four-layered substrate having two inner layers is used as the base substrate 1, and the inner layers are provided as a sheet-shaped wiring layer 6d which is connected with the wirings 6 for a power supply potential and a ground potential, respectively. Although the wiring layer 6d is merely connected with the in-through-hole wiring layer 6b in the arrangement shown in the figure, the layer 6d may be connected with the pad wiring layer 6a and the wiring layer 6d through a via hole wiring layer which longitudinally passes through the respective layers, thereby properly arranging the wiring 6 with the aid of the wiring layer 6d, wherein the wiring layer 6d and the wiring layer 6c are connected to each other through another via hole wiring layer.

The provision of the wiring layer 6d ensures the reduction of an inductance and an increasing degree of freedom for wiring formation.

The invention made by us has been particularly described based on the embodiments, which should not be construed as limiting the invention thereto, and many variations may be possible without departing from the spirit of the invention.

(Effects of the Invention)

The effects attained by typical inventions disclosed in this application are briefly summarized below.

(1) According to the invention, wirings for power supply are provided outwardly of wirings for signal, so that even if external electrodes for power supply of a semiconductor chip is arranged at any positions, they can be readily connected with the wirings for power supply through a bonding wire.

(2) According to the invention, the effect (1) above brings about anther effect that semiconductor chips whose arrangements of external electrodes for power supply differ from each other can be mounted on the same type of base substrate.

(3) According to the invention, the effect (2) also brings about a further effect that general-purpose properties of the base substrate are enlarged.

1. A semiconductor device of the type in which a semiconductor chip is mounted on one surface of a base substrate, an external terminal is formed on the other surface, and a wiring provided on the base substrate is connected at one end thereof with an external electrode of the semiconductor chip on the other surface and at the other end thereof with the external terminal on the other surface, wherein said external terminal includes external terminals for signal and external terminals for power supply, end portions of wirings for signal connected with the external terminals for signal are provided around said semiconductor chip on the one surface and end portions of wirings for power supply connected with the external terminals for power supply are provided outwardly of the end portions of the wirings for signal.

2. A semiconductor device of the type in which a semiconductor chip is mounted on one surface of a base substrate, an external terminal is formed on the other surface, and a wiring provided on the base substrate is connected at one end thereof with an external electrode of the semiconductor chip on the other surface and at the other end thereof with the external terminal on the other surface, wherein said external terminal includes external terminals for signal and external terminals for power supply, end portions of wirings for signal connected with the external terminals for signal are provided around said semiconductor chip on the one surface and end portions of wirings for power supply connected with the external terminals for power supply are provided outwardly of the end portions of the wirings for signal in the form of a ring or a divided rectangular circle.

3. A semiconductor device of the type in which a semiconductor chip is mounted on one surface of a base substrate, an external terminal is formed on the other surface, and a wiring provided on the base substrate is connected at one end thereof with an external electrode of the semiconductor chip on the other surface and at the other end thereof with the external terminal on the other surface, wherein said external terminal includes external terminals for signal and external terminals for power supply, end portions of wirings for signal connected with the external terminals for signal are provided around said semiconductor chip on the one surface and end portions of wirings for power supply connected with the external terminals for power supply are provided outwardly of the end portions of the wirings for signal in the form of a rectangular circle divided at corners thereof.

4. A semiconductor device according to claim 3, wherein wirings connected to said end portions of the wirings for signal are arranged at the corners of said base substrate where no end portion of the wiring for power supply is provided owing to the division.

5. A semiconductor device according to any one of claims 1 to 4, wherein a sheet-shaped wiring layer connected with the wirings for power supply is provided as an inner layer of said base substrate.

6. A semiconductor device according to claim 5, wherein the wirings for power supply include a wiring for a power supply potential and a wiring for a ground potential.

7. A semiconductor device according to claim 6, wherein said one end of the wiring and the external electrode of the semiconductor chip are connected by wire bonding.

8. A semiconductor device of the type which comprises:
a wiring substrate including a first surface and a second surface opposite to said first surface, a power supply wiring and a plurality of signal wirings formed on said first surface, and a plurality of external terminals formed on said second surface wherein said power supply wiring and said signal wirings are, respectively, electrically connected with said plurality of external terminals through a plurality of through-hole wirings;
a semiconductor chip having an integrated circuit on its main surface and a plurality of bonding pads formed thereon and arranged on said first surface of said wiring substrate;
first wires electrically connecting said plurality of signal wirings and corresponding bonding pads therewith;
a plurality of second wires electrically connecting said power supply wirings and corresponding bonding pads; and
a resin body formed on said first surface for sealing said semiconductor chip, said power supply wiring, said plurality of signal wiring, and said first wires and the second wires therewith, wherein said plurality of signal wires, respectively, have a first portion provided between said semiconductor chip and a first main surface of said wiring substrate, and a second portion integrally formed with said first portion and located outwardly of said semiconductor chip, said first wires are connected with said second portions of said signal wirings, and said power supply wirings are positioned outwardly of said second portions of said signal wirings.

9. A semiconductor device according to claim 8, wherein said through-hole wirings are connected to said first portions of said signal wirings.

10. A semiconductor device according to claim 9, wherein said through-hole wirings includes a conductive layer formed in through-holes extending from the first surface to the second surface of said wiring substrate, and said through-holes are formed linearly in the thickness direction of said wiring substrate.

11. A semiconductor device according to claim 8, wherein said wiring substrate is a multi-layered wiring substrate, and said power supply wirings and said signal wirings are, respectively, formed of the same conductor layer.

12. A semiconductor device according to claim 11, wherein said wiring substrate has a power supply plane formed of a conductor layer which is different from the conductor layer forming said power supply wirings and said signal wirings, and said power supply wirings are electrically connected to said power supply plane through said through-hole wirings.

13. A semiconductor device according to claim 8, wherein the plurality of external terminals formed on said second surface include a land electrode connected to said through-hole wiring and a bump electrode formed on said land electrode.

14. A semiconductor device according to claim 8, wherein said wiring substrate and said semiconductor chip, respectively, have a rectangular shape, and said power supply wirings are arranged on a region which is closer to sides of said wiring substrate than to said second portions of said signal wirings.
